(19) United States
(12) Patent Application Publication
(10) Pub. No.: US 2019/0385801 A1
(43) Pub. Date: Dec. 19, 2019

(54) ANTI-GHOST MEMBRANE SWITCH DEVICE

(71) Applicant: Chicony Electronics Co., Ltd., New Taipei City (TW)

(72) Inventors: Chien-Shuo Chen, New Taipei City (TW); Cheng-Fu Tseng, New Taipei City (TW)

(21) Appl. No.: 16/209,406

(22) Filed: Dec. 4, 2018

(30) Foreign Application Priority Data
Jun. 19, 2018 (TW) 107121036

(51) Int. Cl. H01H 13/704; H01H 13/7057; G06F 3/02; H03M 11/00

(52) U.S. Cl. CPC H01H 13/704; H03M 11/003; G06F 3/0202; H01H 13/7057

(57) ABSTRACT

An anti-ghost membrane switch device includes a first membrane layer, a second membrane layer, and a spacing layer. A first surface of the first membrane layer is provided with first trigger points and a first signal line. The first signal line is connected to the first trigger points and extends to a first output terminal. A second surface of the second membrane layer faces towards the first surface and is provided with second trigger points and second signal lines. Ends of the second signal lines are connected to the second trigger points. Another ends of the second signal lines extend to the second output terminal. The second signal lines are not electrically connected with one another. The first signal line of the first membrane layer and the second signal lines are not electrically connected with one another. The spacing layer is between the first and second membrane layers.

### CROSS-REFERENCE TO RELATED APPLICATION

This non-provisional application claims priority under 35 U.S.C. § 119(a) to Patent Application No. 107121036 filed in Taiwan, R.O.C. on Jun. 19, 2018, the entire contents of which are hereby incorporated by reference.

### BACKGROUND

### Technical Field

The instant disclosure relates to a membrane switch device and, more particularly, to an anti-ghost membrane switch device.

### Related Art

A membrane keyboard is a commonly-used input device. A membrane switch of a membrane keyboard usually adopts a matrix circuit. However, an issue of ghost key may be incurred by using such matrix circuit. The ghost key means that a pressing signal in response to a key not pressed is detected or a correct signal is not determined while multi keys are pressed simultaneously. In a case that multi keys need to be pressed simultaneously (e.g., playing a computer game), it inevitably causes troubles.

At present, membrane keyboards usually adopt high impedance design to avoid the issue of ghost key. For instance, each of the keys is connected with a diode. The issue of ghost key can be avoided based upon the difference of forward impedance and backward impedance of the diode. Nevertheless, such design inevitably increases the complexity of fabricating process of the membrane switch, lowers the yield of fabrication, and increases the cost.

### SUMMARY

To address the above issue, an embodiment of an anti-ghost membrane switch device is provided, which comprises a first membrane layer, a second membrane layer, and a spacing layer. The first membrane layer comprises a first surface and a first output terminal. The first surface is provided with a plurality of first trigger points and a first signal line. The first signal line is electrically connected to the first trigger points and extends to the first output terminal. The second membrane layer is disposed on the first membrane layer. The second membrane layer comprises a second surface and a second output terminal. The second surface faces towards the first surface and is provided with a plurality of second trigger points and a plurality of second signal lines. The second trigger points are respectively corresponding to the first trigger points. Ends of the second signal lines are respectively electrically connected to the second trigger points. Another ends of the second signal lines extend to the second output terminal. The second signal lines are not electrically connected with one another. The first signal line of the first membrane layer and the second signal lines are not electrically connected with one another. The spacing layer is between the first membrane layer and the second membrane layer. The spacing layer comprises a plurality of through holes. The through holes are respectively corresponding to the first trigger points and the second trigger points.

Concisely, according to the anti-ghost membrane switch device of embodiments of the instant disclosure, one end of each of the second signal lines of the second membrane layer is connected to the second trigger point, and another end extends to the second output terminal, such that while each corresponding first trigger point and second trigger point conduct with each other, output signals can be individually outputted to avoid the issue of the ghost key. In addition, comparing to the conventional matrix circuit, there are no needs of wire jumping and electrical connection for the first signal line of the first membrane layer and the second signal line of the second membrane layer. There is also no need of high impedance design. As a result, according to embodiments of the instant disclosure, processes of fabrication can be considerably simplified, time of fabrication can be reduced, yield of product can be improved, and cost can be decreased.

### BRIEF DESCRIPTION OF THE DRAWINGS

FIG. 1 illustrates an exploded view of an anti-ghost membrane switch device according to an embodiment of the instant disclosure;

FIG. 2 illustrates a plane view of a first membrane layer according to an embodiment of the instant disclosure;

FIG. 3 illustrates a plane view of a second membrane layer according to an embodiment of the instant disclosure;

FIG. 4 illustrates a schematic view of a circuit of the anti-ghost membrane switch device according to a first embodiment of the instant disclosure;

FIG. 5 illustrates a schematic view of a circuit of the anti-ghost membrane switch device according to a second embodiment of the instant disclosure; and

FIG. 6 illustrates a schematic view of a circuit of the anti-ghost membrane switch device according to a third embodiment of the instant disclosure.

### DETAILED DESCRIPTION

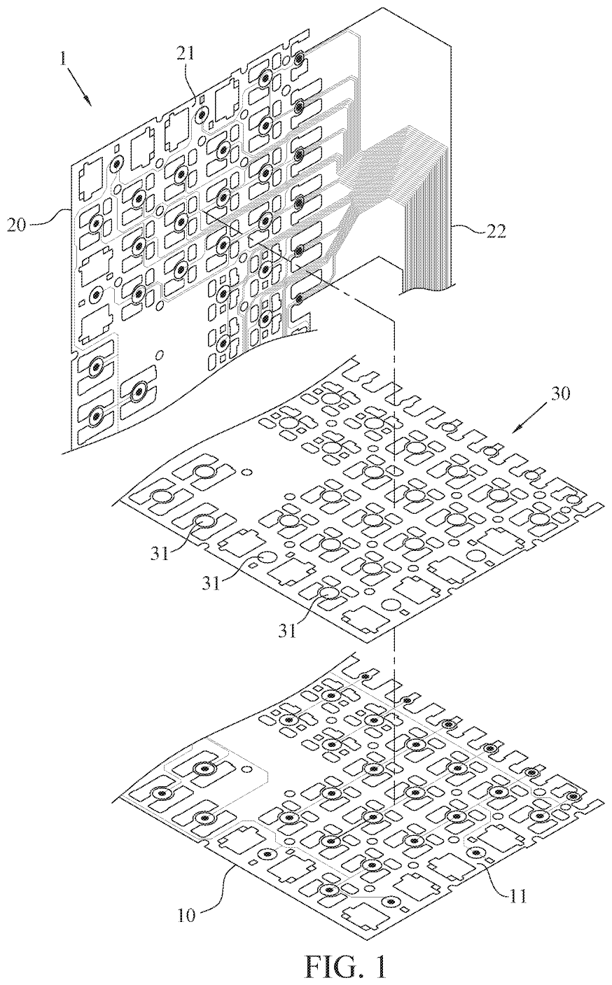

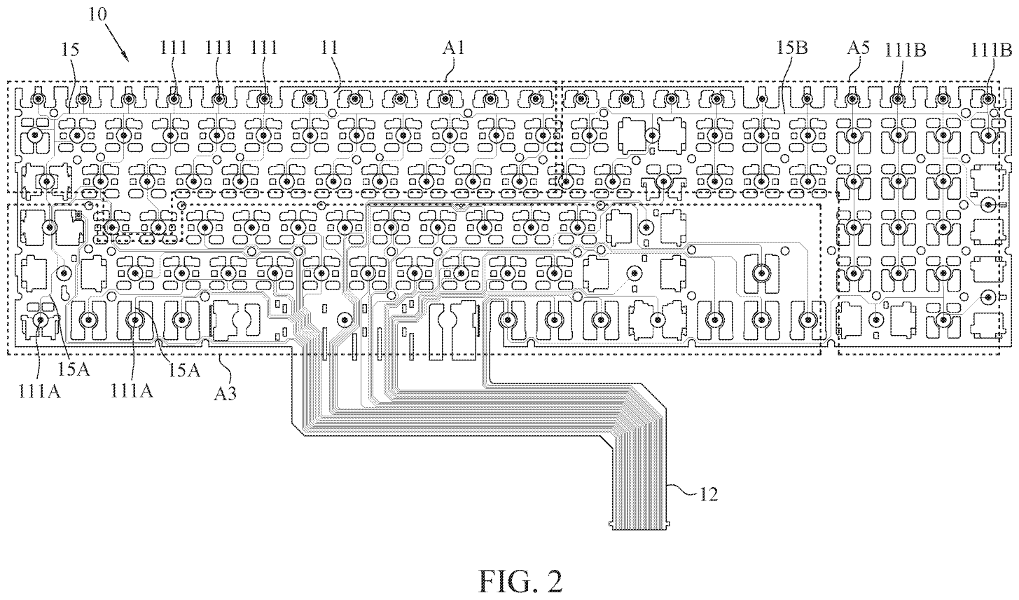

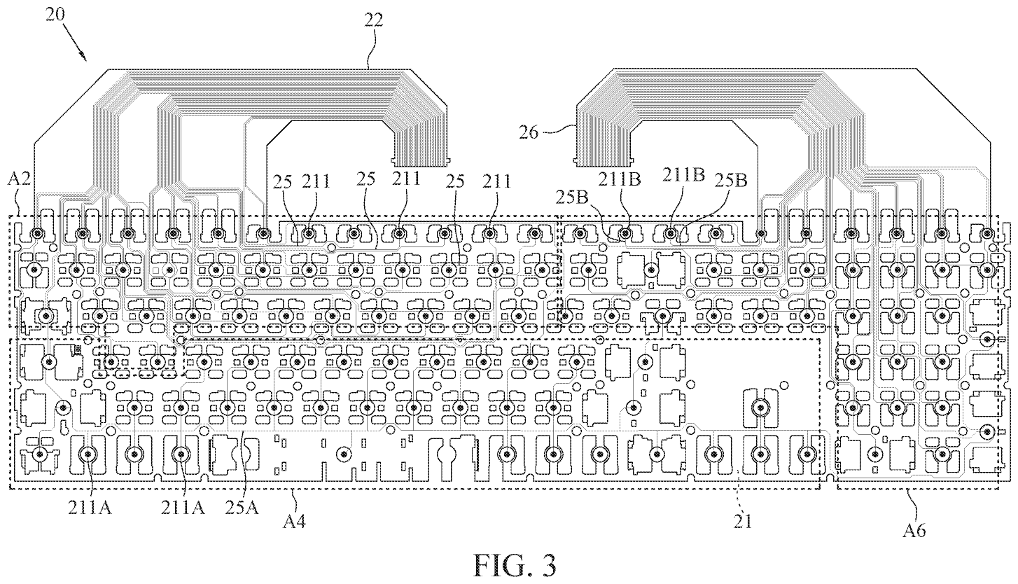

FIG. 1 illustrates an exploded view of an anti-ghost membrane switch device according to an embodiment of the instant disclosure. FIG. 2 illustrates a plane view of a first membrane layer according to an embodiment of the instant disclosure. FIG. 3 illustrates a plane view of a second membrane layer according to an embodiment of the instant disclosure.

As shown in FIG. 1, the membrane switch device 1 is a multi-layer membrane structure, which comprises a first membrane layer 10, a second membrane layer 20, and a spacing layer 30. Wherein, the membrane switch device 1 may be formed as a whole to be of rectangle, square, circle, or other irregular shapes based upon a practice aspect of a product. For instance, in the embodiment, the membrane switch device 1 is adapted to a computer keyboard, and is, but is not limited to, formed to be of rectangle based upon the shape of the computer keyboard.

In addition, as shown in FIG. 1, in the embodiment, the first membrane layer 10 is at the bottommost layer, the second membrane layer 20 is at the topmost layer, and the spacing layer 30 is clamped between the first membrane layer 10 and the second membrane layer 20. For instance, the spacing layer 30 is adhered between the first membrane layer 10 and the second membrane layer 20 by adhesive. Nevertheless, in some embodiments, the relative position of up and down of the first membrane layer 10 and the second membrane layer 20 of the membrane switch device 1 may be altered depending on the needs in practice. In a case that the membrane switch device 1 is adapted to the keyboard, the first membrane layer 10 may close to keys of the keyboard, and the second membrane layer 20 may relatively close to a bottom plate of the key board. Alternatively, the first membrane layer 10 may close to the bottom plate of the keyboard, and the second membrane layer 20 may relatively close to the keys of the keyboard. But the invention is not limited to the above embodiments.

As shown in FIG. 1 and FIG. 2, the first membrane layer 10 comprises a first surface 11 and a first output terminal 12. The first surface 11 is provided with a plurality of first trigger points 111 and a first signal line 15. The first signal line 15 is electrically connected to the first trigger points 111 and extends to the first output terminal 12. In some embodiments, a body of the first membrane layer 10 may be a membrane made by plastic materials such as polyimide, polyethylene terephthalate, and polycarbonate.

As shown in FIG. 1 and FIG. 2, in the embodiment, the first surface 11 is an upper surface of the first membrane layer 10 (while the first membrane layer 10 is the topmost layer, the first surface 11 is a lower surface of the first membrane layer 10). In other words, the first surface 11 of the first membrane layer 10 faces towards the spacing layer 30. The first output terminal 12 extends from a side of the first membrane layer 10 in an integral fashion. For instance, the body of the first membrane layer 10 and the first output terminal 12 may be made in one piece in a machining manner (e.g., stamping or cutting).

As shown in FIG. 1 and FIG. 2, in the embodiment, the first trigger points 111 on the first surface 11 of the first membrane layer 10 are spaced from one another. The first trigger points 111 are at a surface region (e.g., a first area A1 in FIG. 2) of the first surface 11 away from the first output terminal 12. It is not for limitation. The first trigger points may be disposed on different positions according to the needs of different products. In some embodiments, each of the first trigger points 111 may be a conductive substance such as conductive foil (e.g., copper foil, silver foil, or other metal foils) or conductive rubber.

As shown in FIG. 1 and FIG. 2, the first signal line 15 is a metal line. For instance, the first signal line 15 may be a copper line, a silver paste line, or other metal line. The first signal line 15 is not limited to metal materials. Any substance with conductive property can be the material for the first signal line 15. In the embodiment, the first signal line 15 is a line connected with the first trigger points 111 in series. At least an end of the first signal line 15 extends to the first output terminal 12. In some embodiments, the first signal line 15 is formed on the first surface 11 of the first membrane layer 10 in a printing or etching manner.

As shown in FIG. 1 and FIG. 3, the second membrane layer 20 comprises a second surface 21 and a second output terminal 22. In some embodiments, a body of the second membrane layer 20 may be a membrane made by plastic materials such as polyimide, polyethylene terephthalate, and polycarbonate.

As shown in FIG. 1 and FIG. 3, the second surface 21 of the second membrane layer 20 faces towards the first surface 11 of the first membrane layer 10. The second surface 21 is provided with a plurality of second trigger points 211 and second signal lines 25. The second trigger points 211 are spaced from one another and respectively correspond to the first trigger points 111 on the first surface 11 of the first membrane layer 10. In some embodiments, each of the second trigger points 211 on the second surface 21 may be a conductive substance such as conductive foil (e.g., copper foil, silver foil, or other metal foils) or conductive rubber. The second output terminal 22 extends from a side of the second membrane layer 20 in an integral fashion. For instance, the body of the second membrane layer 20 and the second output terminal 22 may be made in one piece in a machining manner (e.g., stamping or cutting).

As shown in FIG. 1 and FIG. 3, each of the second signal lines 25 on the second surface 21 of the second membrane layer 20 is also a metal line. For instance, the second signal line 25 may be a copper line, a silver paste line, or other metal line. The second signal line 25 is not limited to metal materials. Any substance with conductive property can be the material for the second signal line 25. In some embodiments, the second signal line 25 is formed on the second surface 21 of the second membrane layer 20 in a printing or etching manner.

As shown in FIG. 1 and FIG. 3, ends of the second signal lines 25 on the second surface 21 of the second membrane layer 20 are respectively electrically connected to the second trigger points 211, and another ends thereof extend to the second output terminal 22. In other words, each of the second signal lines 25 is independent and not electrically connected to one another. In addition, an end of each of the second signal lines 25 is electrically individually connected to the second trigger points 211 at different locations. Another end of each of the second signal lines 25 directly extend to the second output terminal 22. In other words, each of the second trigger points 211 is extended with one of the second signal lines 25 to the second output terminal 22. Each of the second signal lines 25 is not interlaced with one another. Thus there is no need for additional wire jumping process.

Please refer to FIG. 2 and FIG. 3. In an embodiment, the second trigger points 211 of the second membrane layer 20 are disposed on a second area A2 of the second surface 21. The second area A2 corresponds to the first area A1 provided with the first trigger points in FIG. 2. Since each of the second trigger points 211 respectively needs to be extended with one of the second signal lines 25 to the second output terminal 22, the second area A2 may close to the second output terminal 22 such that the length and distance of line of each of the second signal lines 25 are reduced; therefore, layout of line is easier, and a space for layout of lines is sufficiently used. It is less likely that each of the second signal lines 25 is interlaced with one another; therefore, there is no need for additional wire jumping process.

As shown in FIG. 1, the spacing layer 30 comprises several through holes 31. The through holes 31 respectively correspond to the first trigger points 111 of the first membrane layer 10 and the second trigger points 211 of the second membrane layer 20. Wherein, the bore of each of the through holes 31 may be greater than a covering area of each of the first trigger points 111 and each of the second trigger points 211, such that there is no block between each of the first trigger points 111 and each of the second trigger points 211. As a result, the first trigger points 111 or the second trigger points 211 may close to one another while being pressed. The first trigger points 111 or the second trigger points 211 may be spaced from each other in a certain interval according to the thickness of the spacing layer 30 while being not pressed, such that each of the first trigger points 111 does not contact the corresponding second trigger point 211. For instance, the membrane switch device 1 is adapted to the computer keyboard. The second trigger points 211 of the second membrane layer 20 may be respectively correspondingly disposed below the keys of the computer keyboard. While one of the keys is pressed, the key presses against the corresponding second trigger point 211 to contact the corresponding first trigger point 111, such that a function signal corresponding to the pressed key is generated.

Concisely, according to the configuration of the circuit of the membrane switch device 1 of the embodiments, the issue of the ghost key can be avoided. In addition, processes of fabrication can be considerably simplified, time of fabrication can be reduced, yield of product can be improved, and cost can be decreased. The ghost key means that a pressing signal in response to a key not pressed is detected or a correct signal is not determined while multi keys are pressed simultaneously are determined. The details are illustrated incorporated with the drawing as the following.

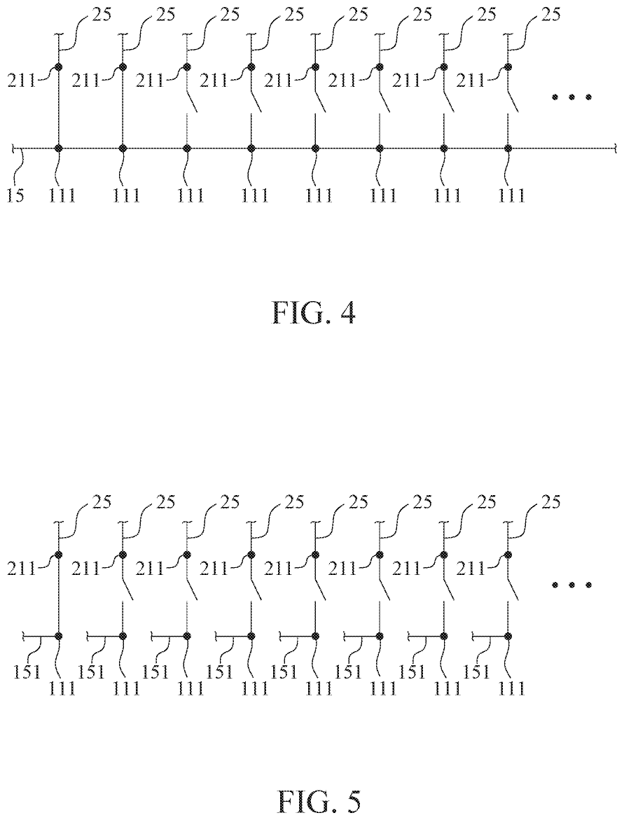

Please refer to FIG. 2, FIG. 3, and FIG. 4. FIG. 4 illustrates a schematic view of a circuit of the anti-ghost membrane switch device according to a first embodiment of the instant disclosure. In the embodiment, the first output terminal 12 of the first membrane layer 10 and the second output terminal 22 of the second membrane layer 20 may be electrically connected to a processor (not shown). While one of the keys is pressed, it correspondingly presses against one of the first trigger points 111 or the second trigger points 211, such that the corresponding first trigger point 111 and the corresponding second trigger point 211 close to and contact with each other (e.g., the leftmost first trigger point 111 and the leftmost second trigger point 211 in FIG. 4 contact and conduct with each other). Thus the first signal line 15 of the first membrane layer 10 merely conduct with the second signal line 25 electrically connected with the contacted second trigger point 211 of the second membrane layer 20. The processor may generate the function signal corresponding to the pressed key according to the conduction state. For instance, the processor may input a detection signal through an end of the first signal line 15, and the processor may receive a feedback signal and generate the function signal corresponding to the pressed key while the second signal line 25 corresponding to the pressed key is conducted.

As aforementioned, since each of the second signal lines 25 electrically connected with the respective second trigger point 211 independently extends to the second output terminal 22, the first signal line 15 of the first membrane layer 10 does not conduct with the second signal lines 25 electrically connected with another second trigger points 211 which are not contacted. Thus the processor does not detect any signals corresponding to the keys not pressed to avoid generating incorrect signals.

Please refer to FIG. 2, FIG. 3, and FIG. 4 again. While two or more keys are pressed simultaneously, the corresponding first trigger point 111 and the corresponding second trigger point 211 close to and contact with each other (e.g., the leftmost two first trigger points 111 and the leftmost two second trigger points 211 in FIG. 4 respectively contact and conduct with each other). The first signal line 15 of the first membrane layer 10 respectively conduct with the two second signal lines 25 electrically connected with the two contacted second trigger points 211 of the second membrane layer 20. The processor may generate the function signal corresponding to the pressed keys according to the conduction of the two second signal lines 25. Therefore, according to the membrane switch device 1 of the embodiments of the instant disclosure, while multi keys are pressed simultaneously, it is possible to respectively determine which keys are pressed to generate correct signals.

Concisely, according to the circuit of the membrane switch device 1 of the embodiments of the instant disclosure comparing to the matrix circuit of the conventional membrane switch, there is no need of electrical connection between the first signal line 15 of the first membrane layer 10 and the second signal lines 25 of the second membrane layer 20. Each of the second signal lines 25 electrically connected with the second trigger points 211 of the second membrane layer 20 independently extends to the second output terminal 22. There are no needs of wire jumping and electrical connection processes. In particular, in a printing process of the matrix circuit of the conventional membrane switch, interlacing portions of lines must be processed with wire jumping process to avoid trigger points being electrically connected to each other. In addition, circuits of an upper membrane layer and a lower membrane layer of the conventional membrane switch need to be electrically connected with each other; therefore, an electrical connection process is required. For instance, the circuits of the upper membrane layer and the lower membrane layer can be electrically connected with each other by an anisotropic conductive film (ACF) attaching machine. Nevertheless, regarding the fabrication of the membrane switch device 1 of the embodiments of the instant disclosure, while the first signal line 15 of the first membrane layer 10 and the second signal lines 25 of the second membrane layer 20 have been printed, the first membrane layer 10 and the second membrane layer 20 can be directly attached to two opposite surfaces of the spacing layer 30, and the fabrication of the membrane switch device 1 is accomplished. There are no needs of the above wire jumping process and the electrical connection process. Processes of fabrication can be considerably simplified, time of fabrication can be reduced, yield of product can be improved, and cost can be decreased. In addition, there is also no need of high impedance design to avoid the issue of ghost key. The cost of fabrication can be further decreased.

As shown in FIG. 5, in an embodiment, the first signal line 15 of the first membrane layer 10 may comprise a plurality of signal lines 151. Ends of the signal lines 151 are respectively electrically connected to the first trigger points 111. Another ends of the signal lines 151 respectively extend to the first output terminal 12. The signal lines 151 are not electrically connected with one another. In other words, each of the first trigger points 111 of the first membrane layer 10 may also be extended with one signal line 151 to the first output terminal 12. Each of the signal lines 151 is not interlaced with each other. As a result, while one of the keys of the keyboard is pressed, it correspondingly presses against one of the first trigger points 111 or the second trigger points 211, such that the corresponding first trigger point 111 and the corresponding second trigger point 211 close to and contact with each other (e.g., the leftmost first trigger point 111 and the leftmost second trigger point 211 in FIG. 5 contact and conduct with each other). Thus the corresponding signal line 151 of the first membrane layer 10 independently conduct with the second signal line 25 electrically connected with the contacted second trigger point 211 of the second membrane layer 20. The processor may generate the function signal corresponding to the pressed key according to the conduction state to avoid the issue of ghost key.

In an embodiment, the membrane switch device 1 may be provided with several signal lines to be adapted to a product with more keys. In addition, in order to efficiently use the space of the first membrane layer 10 and the second membrane layer 20 and facilitate the layout of lines, the layout of lines may be configured in partition. The details are as the following.

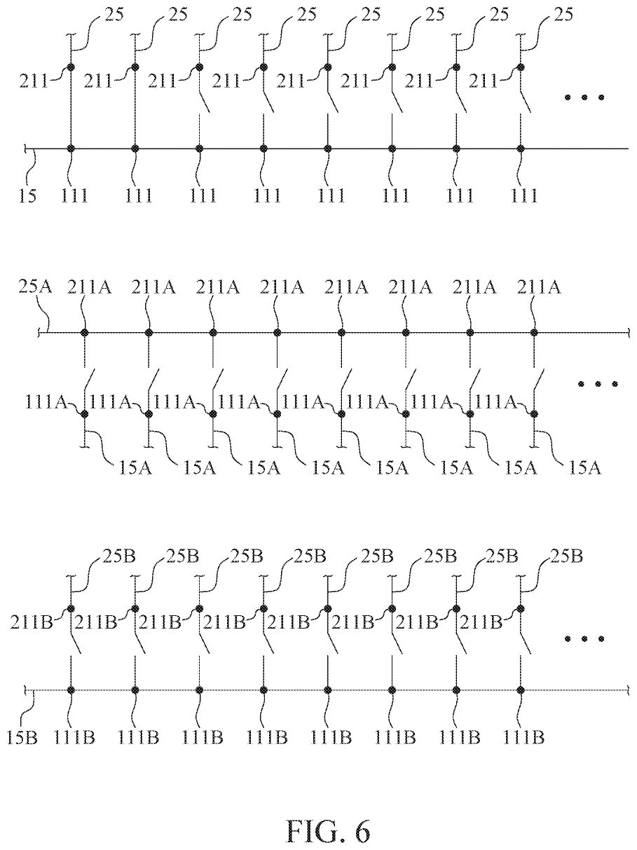

Please refer to FIG. 2, FIG. 3, and FIG. 6. The first surface 11 of the first membrane layer 10 is further provided with a plurality of third trigger points 111A and a plurality of fifth trigger points 111B. For instance, in the embodiment of FIG. 2, the membrane switch device 1 is a membrane switch of a computer keyboard. The first trigger points 111 are at the first area A1 of the first surface 11. The third trigger points 111A are at a third area A3 of the first surface 11. The fifth trigger points 111B are at a fifth area A5 of the first surface 11. The invention is not limited by the above embodiments. In other words, the first trigger points 111, the third trigger points 111A, and the fifth trigger points 111B are respectively concentrated at different areas on the first surface 11 of the first membrane layer 10.

As shown in the third area A3 of FIG. 2 and FIG. 6, the first surface 11 of the first membrane layer 10 is provided with a plurality of third signal lines 15A. Ends of the third signal lines 15A are respectively electrically connected to the third trigger points 111A, and another ends of the third signal lines 15A respectively extend to the first output terminal 12. Each of the third signal lines 15A is independent and not electrically connected to one another. In addition, the third signal lines 15A and the first signal line 15 are not electrically connected to one another. In other words, each of the third trigger points 111A is extended with one third signal line 15A to the first output terminal 12. Each of the third signal lines 15A is not interlaced with each other.

As shown in FIG. 2, in an embodiment, since each of the third trigger points 111A respectively needs to be extended with one of the third signal lines 15A to the first output terminal 12, the third area A3 at which the third trigger points 111A locate may closer to the first output terminal 12 relative to the first area A1 at which the first trigger points 111 locate and the fifth area A5 at which the fifth trigger points 111B locate, such that the length and distance of line of each of the third signal lines 15A are reduced; therefore, layout of lines is easier, and a space for layout of lines is sufficiently used. It is less likely that each of the third signal lines 15A is interlaced with one another; therefore, there is no need for additional wire jumping process.

As shown in the fifth area A5 of FIG. 2 and FIG. 6, the first surface 11 of the first membrane layer 10 is provided with a fifth signal line 15B. The fifth signal line 15B is electrically connected to the fifth trigger points 111B and extends to the first output terminal 12. In the embodiment, the fifth signal line 15B is a line connected with the fifth trigger points 111B in series, and at least an end of the fifth signal line 15B extends to the first output terminal 12. In other embodiments, the fifth signal line 15B may comprise multi lines. Ends of the lines are respectively connected to the fifth trigger points 111B, and another ends extend to another output terminal of the first membrane layer 10. The embodiment is not shown in the drawing. In some embodiments, the fifth signal line 15B may be connected with the first signal line 15 in series (as shown in FIG. 2) or may be configured individually.

Please refer to FIG. 3 and FIG. 6. The second membrane layer 20 may be configured in partition. For instance, as shown in FIG. 3, the second surface 21 of the second membrane layer 20 is provided with a plurality of fourth trigger points 211A and a fourth signal line 25A. The fourth trigger points 211A is at a fourth area A4 on the second surface 21. Wherein, the fourth area A4 corresponds to the third area A3 of the first membrane layer 10, such that the fourth trigger points 211A respectively correspond to the third trigger points 111A of the first membrane layer 10. The fourth signal line 25A is electrically connected to the fourth trigger points 211A and extends to the second output terminal 22. In the embodiment, the fourth signal line 25A is a line connected with the fourth trigger points 211A in series. The fourth signal line 25A of the second membrane 20 and the third signal lines 15A of the first membrane layer 10 are not electrically connected with one another. The fourth signal line 25A and the second signal lines 25 of the first membrane layer 10 are not electrically connected with one another. Therefore, as the circuit shown in the middle of FIG. 6, while one of the keys corresponding to the circuit is pressed, the corresponding third trigger point 111A and the corresponding fourth trigger point 211A close to and contact with each other, such that the fourth signal line 25A merely conducts with the third signal line 15A electrically connected with the contacted third trigger point 111A. The processor may generate the function signal corresponding to the pressed key according to the conduction state. The processor does not detect signals corresponding to the keys not pressed to avoid generating incorrect signals.

Please refer to FIG. 2, FIG. 3 and FIG. 6. The second membrane layer 20 comprises a third output terminal 26. The second surface 21 is provided with a plurality of sixth trigger points 211B and a plurality of sixth signal lines 25B. The sixth trigger points 211B is at a sixth area A6 on the second surface 21. Wherein, the sixth area A6 corresponds to the fifth area A5 of the first membrane layer 10, such that the sixth trigger points 211B respectively correspond to the fifth trigger points 111B of the first membrane layer 10. Ends of the sixth signal lines 25B are respectively electrically connected to the sixth trigger points 211B, and another ends of the sixth signal lines 25B respectively extend to the third output terminal 26. The sixth signal lines 25B are not electrically connected with one another. The fifth signal line 15B of the first membrane layer 10 and the sixth signal lines 25B are not electrically connected with one another. Therefore, as the circuit shown in the bottom of FIG. 6, while one of the keys corresponding to the circuit is pressed, the corresponding fifth trigger point 111B and the corresponding sixth trigger point 211B close to and contact with each other, such that the fifth signal line 15B merely conducts with the sixth signal line 25B electrically connected with the contacted sixth trigger point 211B. The processor may generate the function signal corresponding to the pressed key according to the conduction state. The processor does not detect signals corresponding to the keys not pressed to avoid generating incorrect signals.

As shown in FIG. 3, the sixth area A6 at which the sixth trigger points 211B locate may closer to the third output terminal 26 relative to the fourth area A4 at which the fourth trigger points 211A locate, such that the length and distance of line of each of the sixth signal lines 25B are reduced; therefore, layout of lines is easier, and a space for layout of lines is sufficiently used. It is less likely that each of the sixth signal lines 25B is interlaced with one another; therefore, there is no need for additional wire jumping process.

In addition, please refer to FIG. 2 and FIG. 3. In the embodiment, the first membrane layer 10 comprises an output terminal (the first output terminal 12), the second membrane layer 20 comprise two output terminals (the second output terminal 22 and the third output terminal 26). The invention is not limited by the above embodiments. In some embodiments, the configuration of the interchange the first membrane layer 10 and the second membrane layer 20 may be interchanged. Alternatively, output terminals may be concentrated in the first membrane layer 10 or the second membrane layer 20.

Concisely, regarding the fabrication of the membrane switch device 1 of the embodiments of the instant disclosure, while the signal lines (the first signal line 15, the third signal line 15A, and the fifth signal line 15B) of the first membrane layer 10 and the signal lines (the second signal line 25, the fourth signal line 25A, and the sixth signal line 25B) of the second membrane layer 20 have been respectively printed, the first membrane layer 10 and the second membrane layer 20 can be directly attached to the two opposite surfaces of the spacing layer 30, and the fabrication of the membrane switch device 1 is accomplished. There are no needs of the wire jumping process and the electrical connection process. Considerably, processes of fabrication can be simplified, time of fabrication can be reduced, yield of product can be improved, and cost can be decreased. In addition, there is also no need of additional high impedance design, and the issue of ghost key can be still avoided. The cost of fabrication can be further decreased.

While the instant disclosure has been described by way of example and in terms of the preferred embodiments, it is to be understood that the instant disclosure needs not be limited to the disclosed embodiments. For anyone skilled in the art, various modifications and improvements within the spirit of the instant disclosure are covered under the scope of the instant disclosure. The covered scope of the instant disclosure is based on the appended claims.

What is claimed is:

1. An anti-ghost membrane switch device, comprising:
a first membrane layer comprising a first surface and a first output terminal, the first surface being provided with a plurality of first trigger points and a first signal line, the first signal line being electrically connected to the first trigger points and extending to the first output terminal;
a second membrane layer disposed on the first membrane layer, the second membrane layer comprising a second surface and a second output terminal, the second surface facing towards the first surface and being provided with a plurality of second trigger points and a plurality of second signal lines, the second trigger points being respectively corresponding to the first trigger points, ends of the second signal lines being respectively electrically connected to the second trigger points, another ends of the second signal lines extending to the second output terminal, the second signal lines being not electrically connected with one another, the first signal line of the first membrane layer and the second signal lines being not electrically connected with one another; and
a spacing layer between the first membrane layer and the second membrane layer, the spacing layer comprising a plurality of through holes, the through holes being respectively corresponding to the first trigger points and the second trigger points.

2. The anti-ghost membrane switch device of claim 1, wherein while one of the first trigger points and a corresponding one of the second trigger points close to and contact with each other, the first signal line is conducted with the second signal line electrically connected with the contacted second trigger point.

3. The anti-ghost membrane switch device of claim 1, wherein the second signal lines are not interlaced with one another.

4. The anti-ghost membrane switch device of claim 1, wherein the first signal line is connected with the first trigger points in series, and an end of the first signal line extends to the first output terminal.

5. The anti-ghost membrane switch device of claim 1, wherein the first signal line comprises a plurality of signal line, ends of the signal lines are respectively electrically connected to the first trigger points, another ends of the signal lines respectively extend to the first output terminal, and the signal lines are not electrically connected with one another.

6. The anti-ghost membrane switch device of claim 1, wherein the first surface of the first membrane layer is provided with a plurality of third trigger points and a plurality of third signal lines, ends of the third signal lines are respectively electrically connected to the third trigger points, another ends of the third signal lines respectively extend to the first output terminal, the third signal lines are not electrically connected with one another, and the third signal lines and the first signal line are not electrically connected with one another; the second surface of the second membrane layer is provided with a plurality of fourth trigger points and a fourth signal line, the fourth signal line is electrically connected to the fourth trigger points and extends to the second output terminal, the fourth signal line and the third signal lines are not electrically connected with one another, and the fourth signal line and the second signal lines are not electrically connected with one another.

7. The anti-ghost membrane switch device of claim 6, wherein the third trigger points are closer to the first output terminal relative to the first trigger points.

8. The anti-ghost membrane switch device of claim 6, wherein the fourth signal line is connected with the fourth trigger points in series, and an end of the fourth signal line extends to the second output terminal.

9. The anti-ghost membrane switch device of claim 1, wherein the first surface of the first membrane layer is provided with a plurality of fifth trigger points and a fifth signal line, the fifth signal line is electrically connected to the fifth trigger points and extends to the first output terminal; the second membrane layer comprises a third output terminal, the second surface is provided with a plurality of sixth trigger points and a plurality of sixth signal lines, the sixth trigger points are respectively corresponding to the fifth trigger points, ends of the six signal lines are respectively electrically connected to the sixth trigger points, another ends of the six signal lines respectively extend to the third output terminal, the sixth signal lines are not electrically connected with one another, and the fifth signal line of the first membrane layer and the sixth signal lines are not electrically connected with one another.

10. The anti-ghost membrane switch device of claim 9, wherein the fifth signal line is electrically connected to the first signal line.
